(19) United States
(12) Patent Application Publication
(10) Pub. No.: US 2020/0211833 A1
(43) Pub. Date: Jul. 2, 2020

(54) SEAM-FREE SILICON NITRIDE GAP-FILL TECHNIQUES FOR HIGH ASPECT RATIO TRENCHES

(71) Applicant: Intel Corporation, Santa Clara, CA (US)

(72) Inventors: Ryan Pearce, Beaverton, OR (US); Sudipto Naskar, Portland, OR (US); Nita Chandrasekhar, Hillsboro, OR (US); Minyoung Lee, Hillsboro, OR (US); Harinath Reddy, Beaverton, OR (US); Christopher G. Parker, Portland, OR (US)

(73) Assignee: Intel Corporation, Santa Clara, CA (US)

(21) Appl. No.: 16/632,449

(22) PCT Filed: Aug. 22, 2017
(86) PCT No.: PCT/US2017/047940

§ 371 Date: Jan. 20, 2020

(51) Int. Cl. H01L 21/02; H01L 21/768; H01L 21/762

(52) U.S. Cl. CPC H01L 21/0217; H01L 21/02274; H01L 21/76224; H01L 21/76837; H01L 21/0228

(57) ABSTRACT

An integrated circuit device includes: a semiconductor structure having a high aspect ratio (HAR) feature, the HAR feature having a depth of between 25 nanometers (nm) and 250 nm, a width of between 5 nm and 50 nm, and a depth-to-width aspect ratio of 5:1 or more; and a gap-fill material at least partially filling the HAR feature, the gap-fill material including silicon and nitrogen and being substantially free of a seam located between opposing sides of the HAR feature. A semiconductor process platform includes a nitrogen radical generator to generate nitrogen radicals for delivery to one of the zones, each zone being configured to deliver a separate precursor of a deposition cycle. A method of semiconductor device fabrication includes reacting surfaces of the HAR feature with a silicon precursor, and reacting the silicon-precursed surfaces with nitrogen plasma to form a monolayer of silicon nitride.

### BACKGROUND

With advancements in semiconductor fabrication (e.g., logic, memory, and the like), vertical feature exploitation such as tall, narrow trenches present gap-fill challenges for newer process nodes. For example, current processes for filling narrow trenches are susceptible to pinch-off and void formation, as well as other structural flaws. To this end, a number of non-trivial issues associated with gap fill of narrow trenches remain.

### BRIEF DESCRIPTION OF THE DRAWINGS

FIG. 1 is a top-down view of an example spatial atomic layer deposition (S-ALD) platform for gap-filling seam-free silicon nitride, according to an embodiment of the present disclosure.

FIG. 2 is an example side view of the S-ALD platform of FIG. 1, according to an embodiment of the present disclosure.

FIG. 3 illustrates example S-ALD sequences for forming seam-free silicon nitride gap-fill, according to embodiments of the present disclosure.

FIGS. 4A-4D are cross-sectional views of an example high aspect ratio (HAR) trench formation and seam-free silicon nitride gap-filling and etching process, according to an embodiment of the present disclosure.

FIG. 5A is an illustration of example seams formed in the fabrication of a semiconductor device.

FIG. 5B is an illustration of the example semiconductor device of FIG. 5A, where the silicon nitride filled trenches of the device are seam free, according to an embodiment of the present disclosure.

FIG. 6 is a flow diagram of an example method of semiconductor device fabrication, according to an embodiment of the present disclosure.

FIG. 7 is a flow diagram of an example method of trench filling, according to an embodiment of the present disclosure.

FIG. 8 illustrates an example computing system implemented with the integrated circuit structures or techniques disclosed herein, according to an embodiment of the present disclosure.

These and other features of the present disclosure will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. In short, the figures are provided merely to show example structures.

### DETAILED DESCRIPTION

Techniques are disclosed for seamless gap-filing of nanoscale high aspect ratio (HAR) trenches and other features with silicon nitride. According to some embodiments, such nanoscale HAR features can have a depth to width aspect ratio of 5:1 or more (such as 7:1, 10:1, 12:1, 15:1, 17:1, 20:1, or more), with widths (e.g., trench widths) of 5 nm to 100 nm (e.g., 5 nm, 7 nm, 10 nm, 12 nm, 15 nm, 17 nm, 20 nm, 35 nm, 50 nm, 70 nm, 100 nm, to name a few) and depths of between 25 nm and 250 nm or deeper (e.g., 25 nm, 35 nm, 50 nm, 70 nm, 85 nm, 100 nm, 125 nm, 150 nm, 175 nm, 200 nm, 225 nm, 250 nm, to name a few). In any such cases, the techniques provided herein allow for creation of a seam-free gap-fill, such that during the fill process the approaching opposing sides of the fill material growing within the trench come together without forming a seam. Standard gap-fill processes, on the other hand, yield a detectable vertical seam where the two approaching surfaces come together. This seam can cause structural and performance problems.

General Overview Because of the relatively narrow opening of a given HAR trench, such as a trench to accommodate smaller fin pitch, standard gap-fill techniques fall short. For example, chemical vapor deposition (CVD) often seals the narrow opening to the trench (or so-called pinch-off) before the trench is filled, thus creating a void. Likewise, gap-fill techniques such as deposition-etch-deposition (DED), where a semiconductor trench is partially filled, then etched back to form a V-shape, and then completely filled with a subsequent deposition, are not adequate solutions for certain process nodes (e.g., 12 nm, and especially for 7 nm and beyond). For example, a single DED cycle is not enough to create a void-free fill in narrow trenches for such process nodes. Further, simply repeating the DED cycles (e.g., DEDED, DEDEDED, and so on) introduce throughput and void elimination issues that make them impractical. Atomic layer deposition (ALD) can be used to provide a conformal fill process that tends to reduce formation of such pinch-off based voids, but creates a weak monatomic seam where advancing reactant surfaces from the HAR trench being filled meet. As will be appreciated in light of this disclosure, such a seam generally runs down the center of the trench and includes unreacted components on the reactant surfaces that remain after the ALD process cannot advance any further. Such a seam can lead to problems during subsequent processing of the integrated circuit structure being formed. For example, the seam can come apart or open up during later etching to cause yield issues and shorting. Such seams are a particular problem at nanoscale applications such as 14 nm and subsequent process node (e.g., 10 nm, 7 nm, 5 nm, and beyond) semiconductor devices, which can include HAR features such as trenches that need to be filled with an insulating material such as silicon nitride (SiₓN_{y}, where x can be between 1.0 and 3.0 and y can be between 0.5 and 4.0, which includes but is not limited to Si₃N₄, Si₂N, SiN, and Si₂N₃). As will be further appreciated in light of this disclosure, by using nitrogen (e.g., N₂) plasma in a penultimate operation of a deposition cycle, such as in a spatial ALD (S-ALD) process, seamless formation of silicon nitride can fill HAR features having a relatively high aspect ratio, including HAR bodies having widths in the 5 nm to 100 nm range and depths in the 25 nm to 250 nm range for the newer process nodes.

Thus, techniques are provided herein for seamless gap-filling of nanoscale high aspect ratio (HAR) trenches and other features with silicon nitride. The trench configurations can vary from one embodiment to the next, but generally the trenches being filled have a depth to width aspect ratio of 5:1 or more (e.g., 7:1, 10:1, 15:1, 20:1, to name a few examples), with relatively narrow widths of, for instance, 100 nm or less (e.g., 5 nm, 7 nm, 10 nm, 12 nm, 15 nm, 20 nm, 25 nm, 35 nm, 50 nm, 70 nm, and any other widths less than 100 nm) and relatively deep trenches of, for instance, 20 nm or greater (e.g., 25 nm, 30 nm, 35 nm, 40 nm, 50 nm, 70 nm, 100 nm, 150 nm, 200 nm, 250 nm, 500 nm, and others). In any such cases, the techniques provided herein allow for creation of a seam-free gap-fill, such that during the fill process the approaching opposing sides of the fill material growing within the trench come together without forming a seam. In accordance with some embodiments of the present disclosure, S-ALD is combined with plasma passivation and radical-based chemistry to provide void-free and seam-free silicon nitride gap-fill techniques for HAR structures having widths in the range of 5 nm to 100 nm using 14 nm, 10 nm, 7 nm, 5 nm, and beyond process nodes.

In one such embodiment, an integrated circuit (IC) device includes a semiconductor structure having a high aspect ratio (HAR) feature. The HAR feature has a depth of between 25 nanometers (nm) and 250 nm, a width of between 5 nm and 50 nm, and a depth-to-width aspect ratio of 5:1 or more. The IC device also includes a gap-fill material at least partially filling the HAR feature. The gap-fill material includes silicon and nitrogen (e.g., silicon nitride) and is free of a vertical seam along a vertical plane that runs between opposing sides of the HAR feature. In another such embodiment, a semiconductor process platform includes a process chamber and a plurality of precursor zones within the process chamber. Each precursor zone is configured to deliver a separate precursor of a deposition cycle. The platform further includes a susceptor configured to hold a semiconductor wafer and to move relative to the zones to complete the deposition cycle on the wafer, and a nitrogen radical generator to generate nitrogen radicals for delivery to one of the zones.

Numerous applications for the techniques provided herein will be apparent in light of this disclosure. Example applications include HAR structures (e.g., deep narrow trenches and the like having at least a 5:1 aspect ratio of feature depth to feature width). Example trench widths include 5-100 nm (or any subrange thereof, such as, e.g., 5-10, 5-25, 5-50, 5-75, 10-25, 10-50, 10-75, 10-100, 25-50, 25-75, 25-100, 50-75, 50-100, or 75-100 nm) or any other suitable range or value as will be apparent in light of this disclosure. Example trench depths include 25-500 nm (or any subrange thereof, such as, e.g., 25-100, 25-250, 25-400, 50-100, 50-250, 50-400, 50-500, 100-250, 100-400, 100-500, or 250-500 nm) or any other suitable range or value as will be apparent in light of this disclosure. Example depth-to-width aspect ratios (D:W) include 5:1 or greater, 7:1 or greater, 10:1 or greater, 12:1 or greater, 15:1 or greater, 20:1 or greater, or any other suitable threshold ratio as will be apparent in light of this disclosure. Note that the widths and depths of features described herein, such as the widths/depths of HAR trenches, may relate to widths/depths along a given plane (e.g., a width along a given horizontal plane, a depth along a given vertical plane), maximum widths/depths (e.g., the maximum width of a given trench, the maximum depth of a given trench), and/or widths/depths between two other features (e.g., the width of a trench between two fins, the depth of a trench between the underlying substrate and the overlying layer), for example.

Note that, as used herein, the expression “X includes at least one of A or B” refers to an X that may include, for example, just A only, just B only, or both A and B. To this end, an X that includes at least one of A or B is not to be understood as an X that requires each of A and B, unless expressly so stated. For instance, the expression “X includes A and B” refers to an X that expressly includes both A and B. Moreover, this is true for any number of items greater than two, where “at least one of” those items is included in X. For example, as used herein, the expression “X includes at least one of A, B, or C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, or C is not to be understood as an X that requires each of A, B, and C, unless expressly so stated. For instance, the expression “X includes A, B, and C” refers to an X that expressly includes each of A, B, and C. Likewise, the expression “X included in at least one of A or B” refers to an X that may be included, for example, in just A only, in just B only, or in both A and B. The above discussion with respect to “X includes at least one of A or B” equally applies here, as will be appreciated.

Seam Formation with Standard Process

Void-free silicon nitride can be formed from various precursors using techniques such as atomic layer deposition (ALD), including spatial ALD (S-ALD), coupled with a plasma passivation strategy. S-ALD efficiently builds a single molecular layer (monolayer) of silicon nitride every ALD cycle at relatively high speeds and without requiring high vacuum conditions or the like. For example, a silicon precursor can be used in an ALD cycle to deposit silicon atoms while ammonia (NH₃) plasma can be used later that cycle to deliver the nitrogen to bond with the deposited silicon and form silicon nitride. However, because the filling of HAR features using ALD causes converging surfaces (e.g., from the trench walls inward) of the deposited silicon nitride to meet, seams (which can be as thin as a monolayer) can form where the converging surfaces meet.

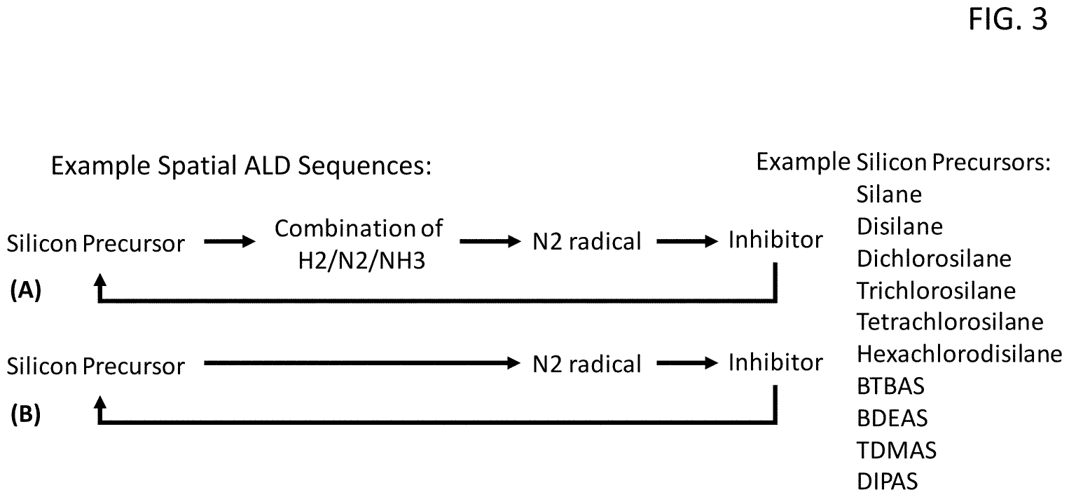

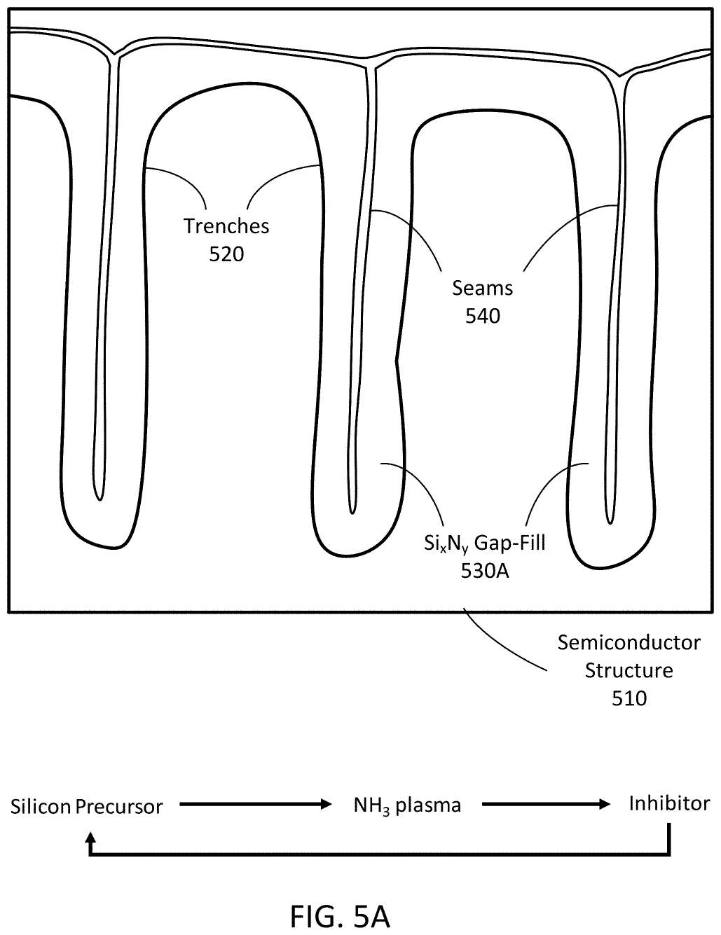

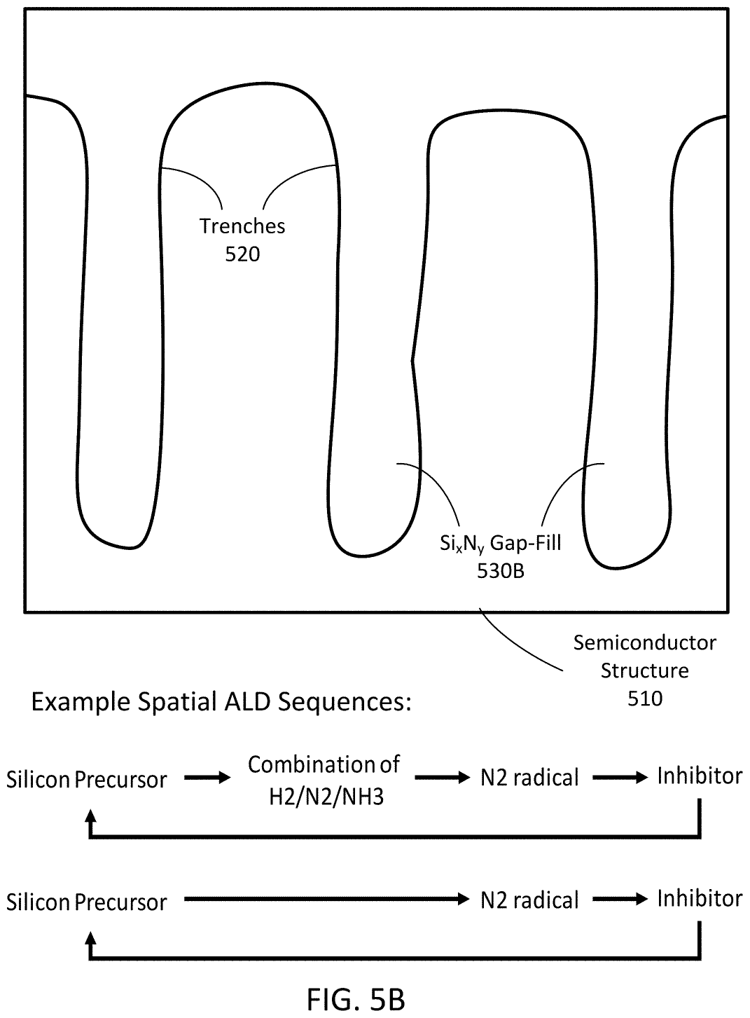

For example, FIG. 5A shows seams 540 formed during ALD of converging ALD surfaces using a silicon precursor and ammonia plasma for the nitrogen source. In FIG. 5A, a semiconductor structure 510 includes trenches 520 filled with silicon nitride gap-fill 530A using a standard process. Here, the ALD sequence includes a silicon precursor (see FIG. 3 for example precursors), followed by ammonia plasma, and then followed by an inhibitor. The seams 540, for example, can include unreacted hydrogen from precursors or reactants (such as from the ammonia), but whose space blocks the passage (e.g., through steric interference) of any further precursor or reactant to the surface sites of the advancing surfaces of hydrogen-terminated silicon nitride monolayers. The seams 540 are monatomic in scale, are not bonded, and often fail during downstream etch processes near the HAR features. For example, the seams 540 lead to uneven trench recess etch causing shorting and voids. The seams can also cause the trenches 520 to etch unevenly.

As will be appreciated in light of this disclosure, the weak monolayer seams result from electrostatic repulsion of two parallel hydrogen-terminated surfaces from the ammonia precursor. As the silicon nitride monolayer film grows from both sides, the hydrogen-terminated surfaces eventually get close enough that the ammonia plasma species cannot enter the space between the two advancing surfaces. This prevents the cross-linking of the two approaching surfaces and instead creates a seam of surface-terminating hydrogen atoms. Note that the seams 540 in FIG. 5A do not extend down to the bottom of trenches 520; however, they exist in at least a majority of a vertical plane between opposing sides of the trenches 520, which is undesirable as described herein.

According to one or more embodiments of the present disclosure, nitrogen (N₂) plasma is used as a nitrogen source during the S-ALD process. The nitrogen plasma forms non-hydrogen terminated surfaces that allows cross-linking between the two approaching surfaces, leading to seam-free gap-fill. The nitrogen plasma does not leave hydrogen-terminated chains in the trench. The process further allows for seam-free silicon nitride gap-fill that etches uniformly across the trench depth. For example, FIG. 5B illustrates the example semiconductor device 510 of FIG. 5A according to an embodiment of the present disclosure, where the trenches 520 are filled with silicon nitride 530B and are seam free as a result of using nitrogen (N₂) plasma as a nitrogen source during the S-ALD process (as opposed to just using ammonia). In the example embodiment of FIG. 5B, trenches 520 are completely free of any seams. However, in other embodiments, the structures formed using the techniques described herein may include silicon nitride filled trenches that are substantially free of seams, such that a seam only exists along at most 25, 20, 15, 10, or 5% of any given vertical plane between opposing sides of the silicon nitride filled trench. In some embodiments, substantially free of a seam means having a seam in no more than 25, 20, 15, 10, or 5% of the gap-fill material within the HAR feature. In some such embodiments, if a seam does form using silicon nitride gap-fill techniques described herein, that seam will have a depth that is less than 25, 20, 15, 10, or 5% of the total depth of the gap-fill material (e.g., within the HAR feature) in which the seam exists. In some cases, a given trench that is gap-filled with silicon nitride may be substantially free of seams such that the silicon nitride material has one or more seams where each seam has a maximum height or depth that is no more than 25, 20, 15, 10, or 5% of the maximum height or depth of the trench. Regardless of whether the techniques described herein achieve a complete or substantially seam-free silicon nitride filled trench, benefits are still derived from the techniques of this disclosure as compared to standard gap-fill processes that form seams in at least a majority of at least one vertical plane between opposing sides of the trench being filled. In other words, the techniques described herein can be used to at least reduce the seam size, and in some cases, form silicon nitride gap-fill material that is seam-free within an HAR feature.

Also note that although trenches 520 are completely filled in FIGS. 5A and 5B, a given trench need not be completely filled with silicon nitride to benefit from the techniques described herein. For instance, partial fills of at least 10, 20, 30, 40, 50, 60, 70, 80, or 90% of a given trench depth can also benefit from the techniques described herein, as those at least partially filled trenches (e.g., HAR features) would still benefit from being substantially or completely seam free as compared to standard silicon nitride gap-fill processes.

In additional embodiments of the present disclosure, to improve delivery of the active nitrogen species all the way to the bottom of the trench, a nitrogen radical generator (such as a standalone nitrogen radical generator) is used in the S-ALD process. The radicals generated by such devices have a longer mean free path (and thus survive longer than when delivered as nitrogen plasma, which improves their probability of reaching the bottom of the trench) than routing nitrogen in the same line used to deliver ammonia to create a nitrogen plasma.

System Architecture

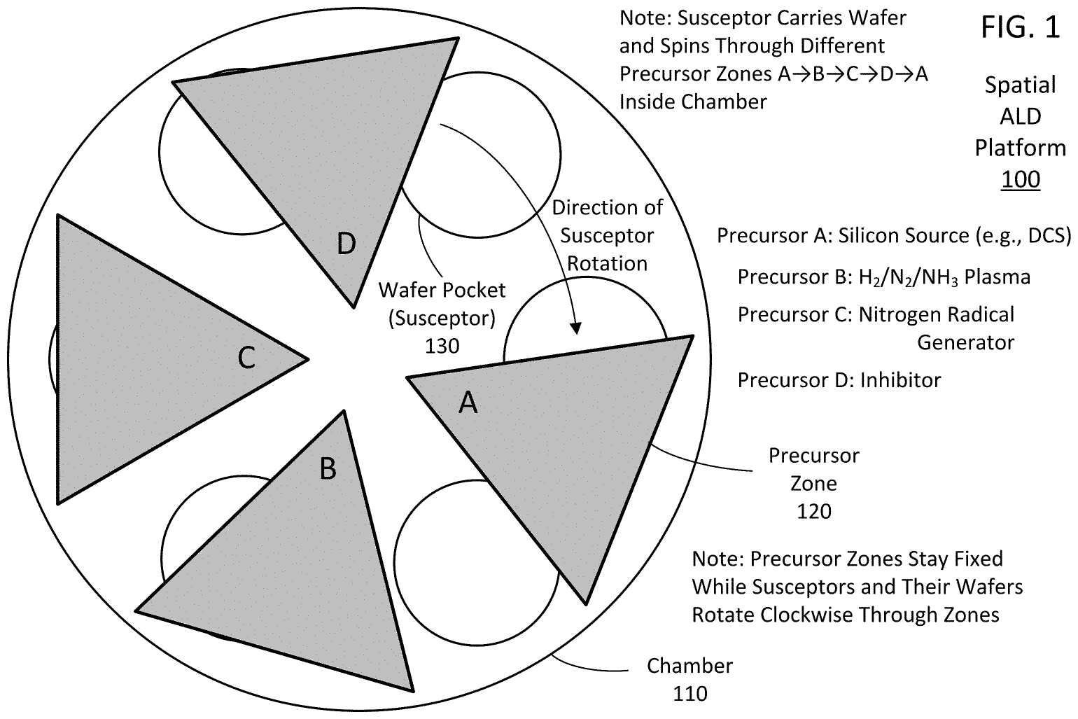

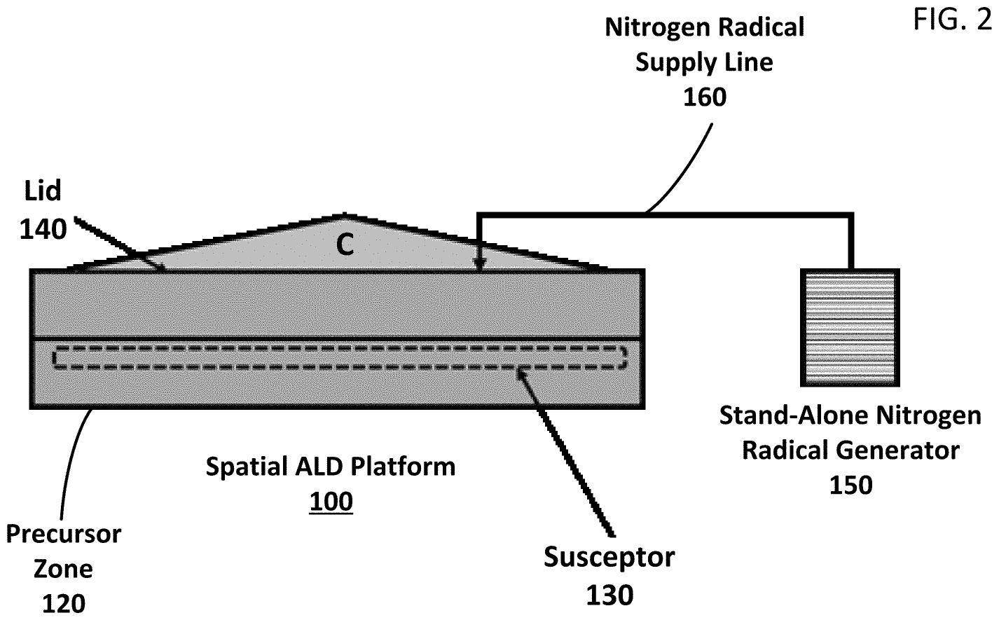

FIG. 1 is a top-down view of an example spatial ALD (S-ALD) platform 100 for gap-filling seam-free silicon nitride, according to an embodiment of the present disclosure. FIG. 2 is an example side view of the S-ALD platform 100 of FIG. 1, according to an embodiment of the present disclosure. The setup in FIGS. 1-2 illustrates an example S-ALD platform 100 with an additional stand-alone nitrogen radical generator unit 150 for practicing various embodiments of the present disclosure. The stand-alone nitrogen radical generator 150 may be external to the S-ALD platform 100 (for example, in some embodiments, the stand-alone nitrogen radical generator 150 may be visible outside the S-ALD platform 100). In some embodiments, the stand-alone nitrogen radical generator 150 includes a dedicated delivery line 160 (or other dedicated delivery path) to the S-ALD platform 100.

Referring to FIGS. 1-2, the S-ALD platform 100 includes a chamber 110 housing two or more precursor zones 120 and one or more wafer pockets (susceptors) 130. In some embodiments, a wafer handler is provided instead of or in addition to the susceptors. The wafer handler moves a semiconductor wafer within or in-and-out of the chamber 110. Silicon wafers awaiting S-ALD processing (e.g., to fill a high aspect ratio trench with silicon nitride) are placed in the susceptors (e.g., singly, through one or more of the lids 140). The susceptors are then subjected to the S-ALD process carried out by the precursor zones 120. For example, in FIG. 1, four precursor zones 120 are illustrated, separately labeled A, B, C, and D. Each precursor zone 120 is responsible for a separate precursor (e.g., surface reactant) during the ALD cycle. For example, precursor zone A provides a silicon source, such as silane (SiH₄), disilane (Si₂H₆), dichlorosilane (DCS, H₂SiCl₂), or the like (e.g., refer to FIG. 3). The silicon source binds with earlier deposited nitrogen, for example, to form silicon nitride.

Precursor zone B supplies any combination of hydrogen (H₂), nitrogen (N₂), and ammonia (NH₃) plasma as part of the nitridation of the silicon precursor with a hydrogen termination. Precursor zone C then supplies the nitrogen radicals (e.g., plasma) from the stand-alone nitrogen radical generator source 150 (e.g., by dedicated supply line 160). This forms a silicon nitride monolayer with the recently deposited silicon and without terminating hydrogen atoms. Precursor zone D then supplies an inhibitor, such as at the top of the trench, to reduce or prevent adsorption of the next cycle of silicon precursor in undesired locations. The process then repeats with another application of precursor zones A, B, C, and D to form another monolayer of silicon nitride, and keeps repeating these cycles until the trench is filled.

FIG. 3 illustrates example S-ALD sequences for forming seam-free silicon nitride gap-fill, according to embodiments of the present disclosure. Sequence A is as described above in reference to FIG. 1. However, in addition to the above-mentioned silicon precursors (silane, disilane, and dichlorosilane), other example silicon precursors include trichlorosilane (HSiCl₃), silicon tetrachloride (tetrachlorosilane, SiCl₄), hexachlorodisilane (Si₂Cl₆), bis(tertiary-butylamino)silane (BTBAS), bis(diethylamino)silane (BDEAS), tris(dimethylamino)silane (TDMAS), and diisopropylamino silane (DIPAS). Sequence B is similar to sequence A, but the second process (combination of hydrogen, nitrogen, and ammonia plasma) is skipped.

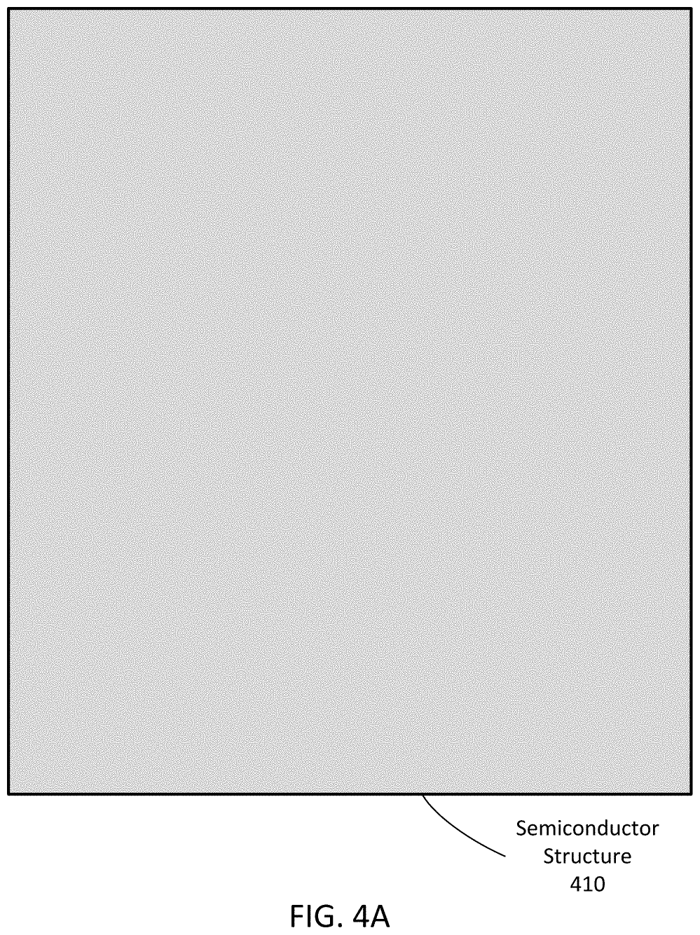

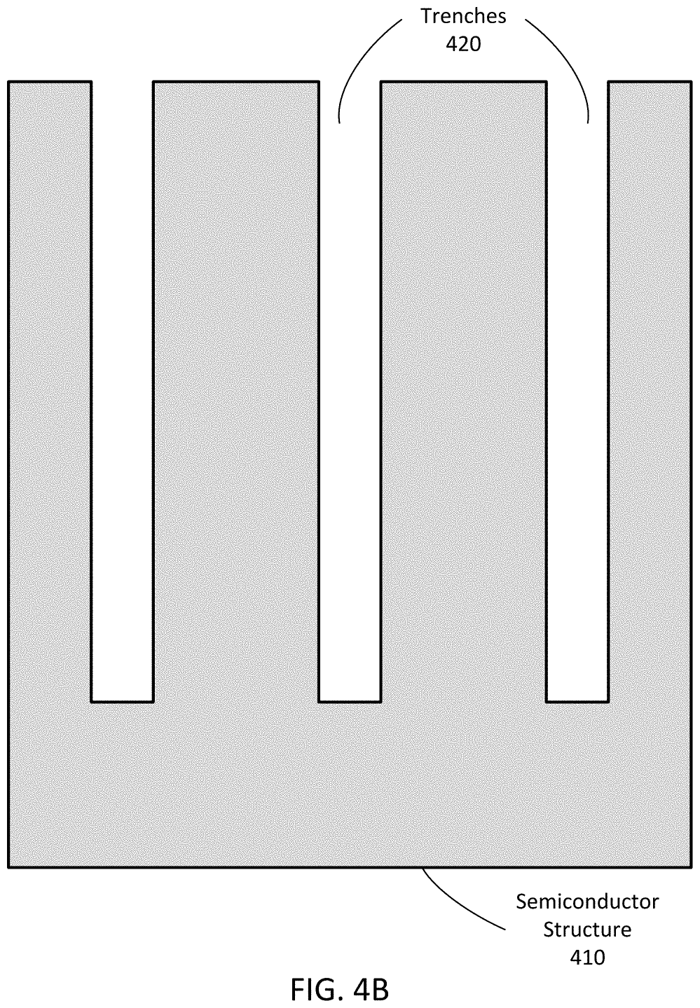

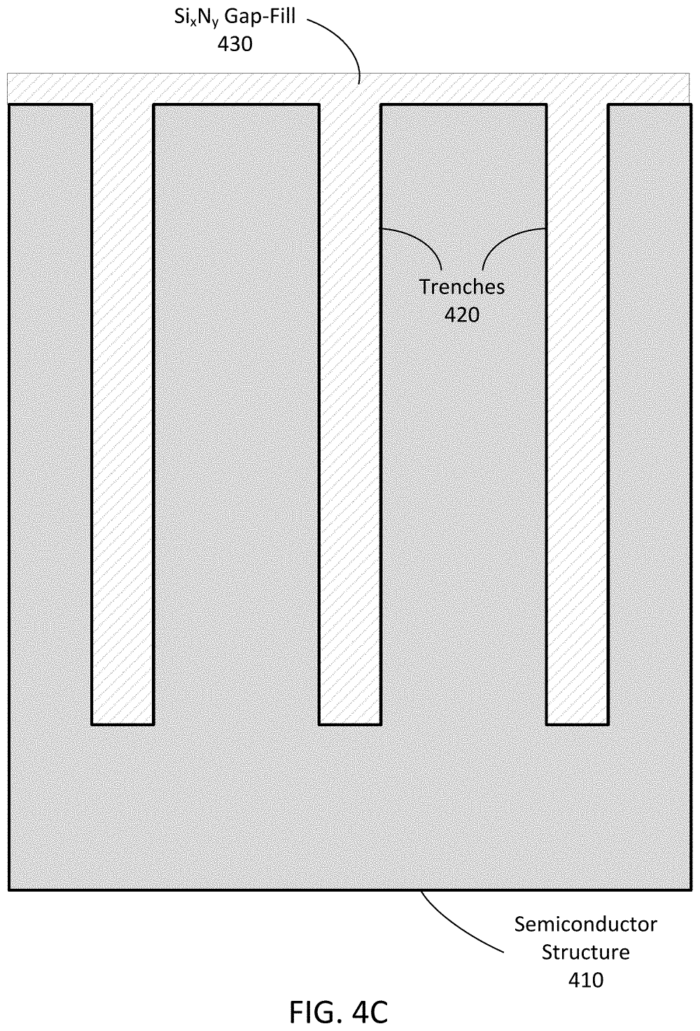

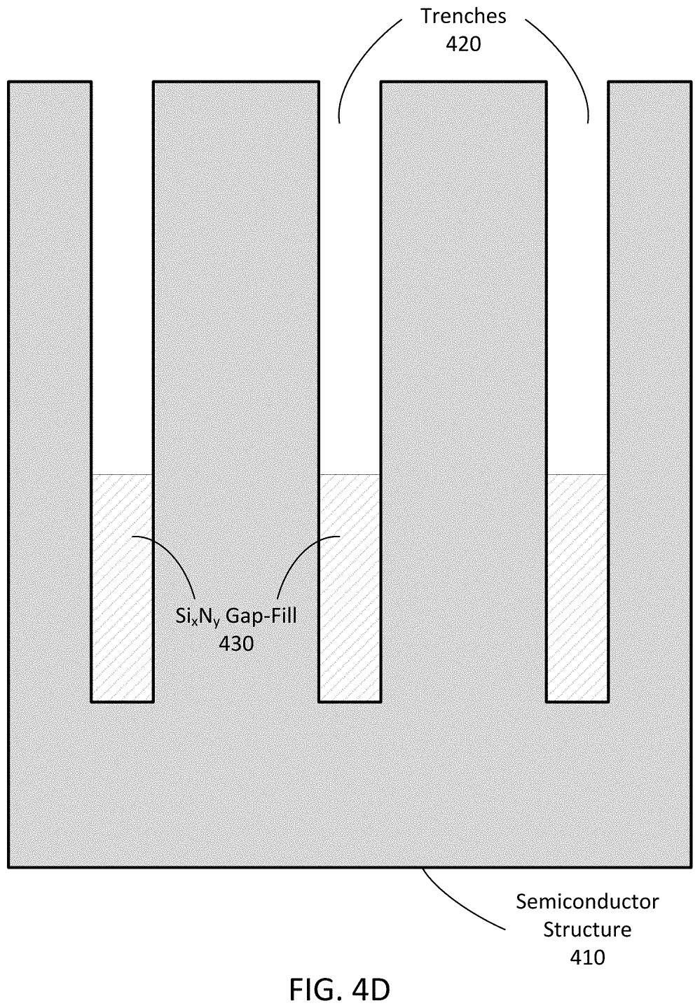

FIGS. 4A-4D are cross-sectional views of an example high aspect ratio (HAR) trench formation and seam-free silicon nitride gap-filling and etching process, according to an embodiment of the present disclosure. The process in FIGS. 4A-4D can be, for example, a semiconductor fabrication process, such as an integrated circuit or integrated circuit device fabricated with a 7 nm process node, 5 nm process node, or beyond, or it can be a nanoscale (e.g., between 1 nm and 100 nm) fabrication process, or other similar process. In some embodiments, the HAR trenches are for transistor architecture. In some other applications, the HAR trenches are for patterning applications. In some embodiments, initial aspect ratios (e.g., into base silicon substrate) may be smaller (e.g., less than 5:1), however when other features such as liners, barriers, or the like are considered, the resulting space to be filled can be very tight and have a high aspect ratio (e.g., at least 5:1, such as 10:1, 15:1, or more).

In FIG. 4A, a semiconductor structure 410 is provided. The semiconductor structure can be a bulk semiconductor, bulk dielectric, or some integrated circuit structure including one or more layers. The semiconductor structure 410 can have a flat or relatively flat top, such as a planarizing or otherwise flat layer or layers (possibly including substrate, such as semiconductor substrate) in a semiconductor process, or be a suitable material for nanoscale processing. In FIG. 4B, high aspect ratio (HAR) features, in this case, trenches 420, are formed in the surface of the semiconductor structure 410. For example, in one embodiment, the HAR features (e.g., trenches 420) are within and in direct contact with a bulk body of semiconductor material making up the semiconductor structure 410. The HAR features have a depth to width ratio of at least 10:1 (in this case, 10:1, but other embodiments are not so limited, such as 5:1, 7:1, 15:1, 20:1, or more). Further, the HAR features have a width between 5 nm and 50 nm (for example, 5 nm, 10 nm, 20 nm, or 50 nm). The walls of the trenches 420 can be straight. The trenches 420 can be formed using semiconductor fabrication or nanoscale manufacturing techniques such as photolithography and etching. For example, deep etching can be used to fabricate semiconductor fins between the trenches 420, each fin being defined by two adjacent trenches 420 The fins may be part of semiconductor devices such as transistors, capacitors, and the like.

In FIG. 4C, silicon nitride gap-fill 430 is formed (in this case, deposited) seamlessly and without voids in the trenches 420 using S-ALD according to embodiments described or otherwise disclosed herein. For example, the silicon nitride gap-fill 430 fills the HAR features (e.g., trenches) 420 and is free of any vertical seams along a vertical plane that runs between opposing sides of the HAR features. In FIG. 4D, recess etching is performed on the gap-fill 430 (e.g., after planarizing the gap-fill 430 to the top of the semiconductor structure 410), evenly etching the gap-fill 430 to a uniform or near uniform height in the trenches 420. Here, the even recess etching is made possible by the lack of vertical seams within the gap-fill 430 located in the trenches 420. After the recess etching, the gap-fill 430 partially fills the trenches 420, with no voids and no seams (e.g., no vertical seams) within the gap-fill 430.

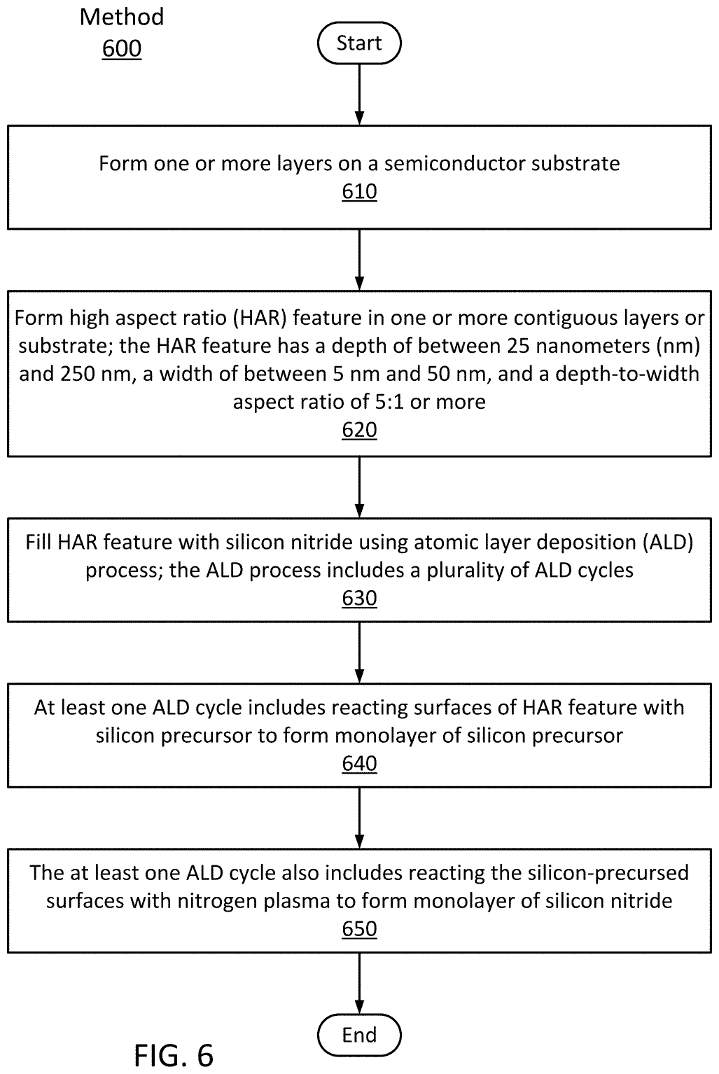

Methodology FIG. 6 is a flow diagram of an example method 600 of semiconductor device fabrication, according to an embodiment of the present disclosure. The method 600 includes forming 610 one or more layers (e.g., semiconductor fabrication layers) on a semiconductor substrate, and forming 620 a high aspect ratio (HAR) feature in one or more contiguous ones of the layers and substrate. The HAR feature has a depth of between 25 nanometers (nm) and 250 nm, a width of between 5 nm and 50 nm, and a depth-to-width aspect ratio of 5:1 or more. The method also includes filling 630 the HAR feature with silicon nitride using an atomic layer deposition (ALD) process. The ALD process includes a plurality of ALD cycles. At least one ALD cycle includes reacting 640 surfaces of the HAR feature with a silicon precursor to form a monolayer of the silicon precursor, and reacting 650 the silicon-precursed surfaces with nitrogen plasma to form a monolayer of silicon nitride.

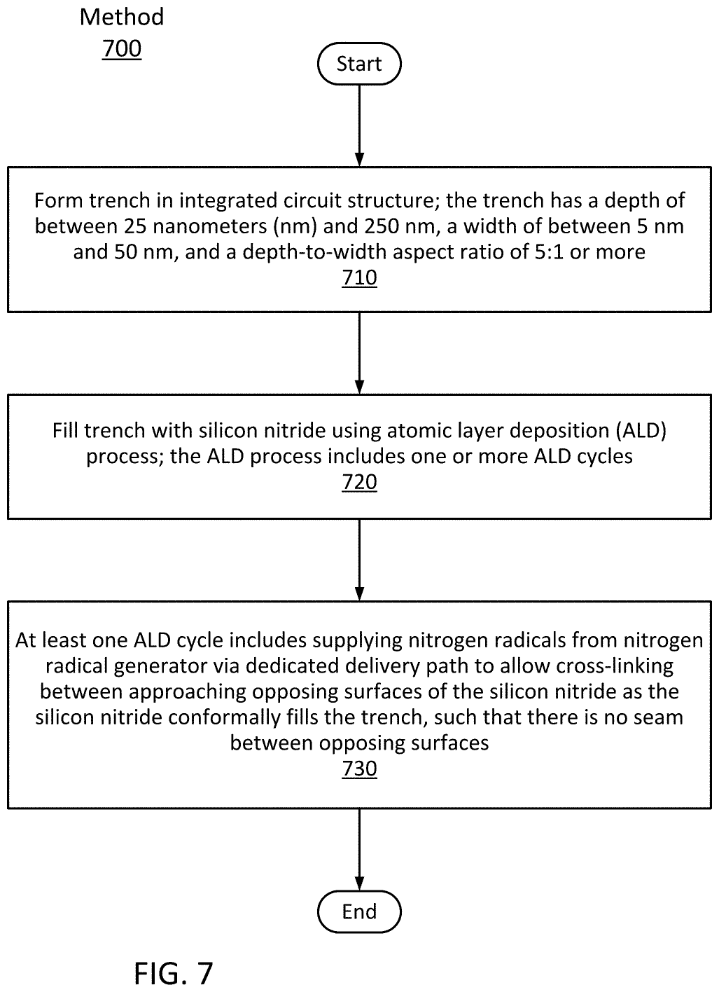

FIG. 7 is a flow diagram of an example method 700 of trench filling, according to an embodiment of the present disclosure. The method 700 includes forming 710 a trench in an integrated circuit structure. The trench has a depth of between 25 nanometers (nm) and 250 nm, a width of between 5 nm and 50 nm, and a depth-to-width aspect ratio of 5:1 or more. The method 700 further includes filling 720 the trench with silicon nitride using an atomic layer deposition (ALD) process. The ALD process includes one or more ALD cycles. At least one ALD cycle includes supplying 730 nitrogen radicals from a nitrogen radical generator via a dedicated delivery path to allow cross-linking between approaching opposing surfaces of the silicon nitride as the silicon nitride conformally fills the trench, such that there is no seam between the opposing surfaces.

The above and other methods disclosed herein can be implemented, for example, on the S-ALD platform 100 of FIGS. 1-2. While the above example methods appear as a series of operations or stages, it is to be understood that there is no required order to the operations or stages unless specifically indicated.

Example System

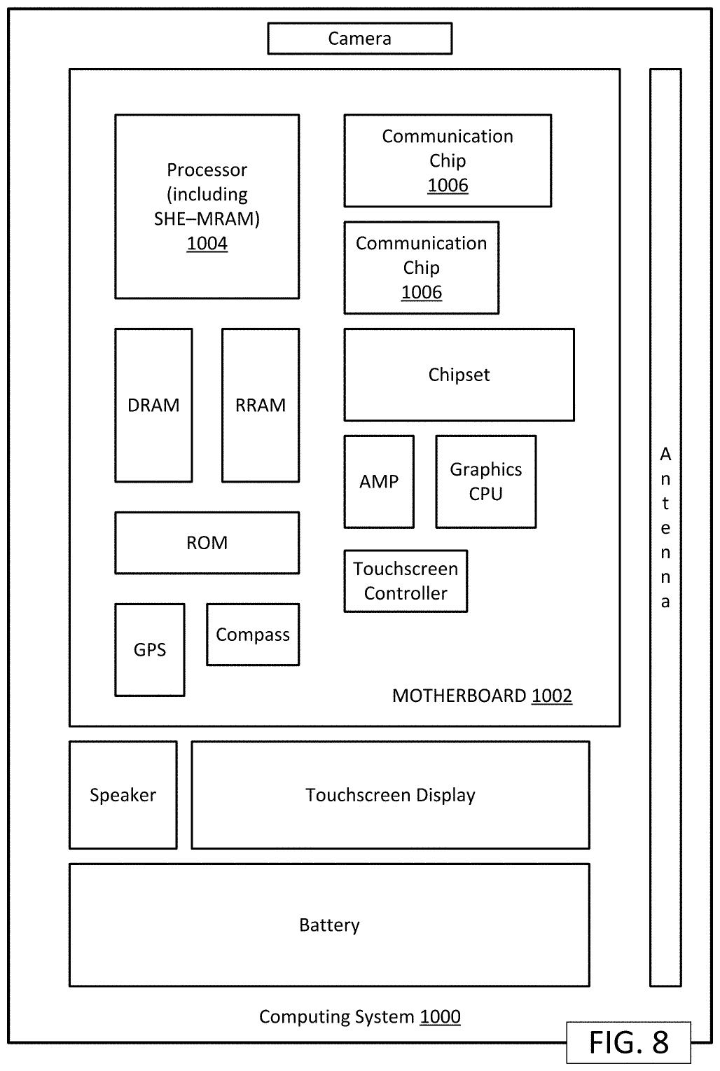

FIG. 8 illustrates a computing system 1000 implemented with the integrated circuit structures or techniques disclosed herein, according to an embodiment of the present disclosure. As can be seen, the computing system 1000 houses a motherboard 1002. The motherboard 1002 may include a number of components, including, but not limited to, a processor 1004 (including HAR features) and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, to name a few examples.

Depending on its applications, computing system 1000 may include one or more other components that may or may not be physically and electrically coupled to the motherboard 1002. These other components may include, but are not limited to, volatile memory (e.g., DRAM), nonvolatile memory (e.g., read-only memory (ROM), resistive random-access memory (RRAM), and the like), a graphics processor, a digital signal processor, a crypto (or cryptographic) processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices (e.g., one or more HAR features) formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, and the like, that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices (e.g., one or more HAR features) formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices (e.g., one or more SHE-MRAM memory cells) formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices (e.g., one or more SHE-MRAM memory cells) formed using the disclosed techniques, as variously described herein.

### FURTHER EXAMPLE EMBODIMENTS

The following examples pertain to further embodiments, from which numerous permutations and configurations will be apparent.

Example 1 is an integrated circuit device including: a semiconductor structure having a high aspect ratio (HAR) feature, the HAR feature having a depth of between 25 nanometers (nm) and 250 nm, a width of between 5 nm and 50 nm, and a depth-to-width aspect ratio of 5:1 or more; and a gap-fill material at least partially filling the HAR feature, the gap-fill material including silicon and nitrogen and being substantially free of a seam located between opposing sides of the HAR feature.

Example 2 includes the subject matter of Example 1, wherein being substantially free of a seam means having a seam in no more than 25% of the gap-fill material within the HAR feature.

Example 3 includes the subject matter of Example 1 or 2, wherein being substantially free of a seam means being completely free of a vertical seam in the gap-fill material along any vertical plane between opposing sides of the HAR feature.

Example 4 includes the subject matter of any of Examples 1-3, wherein the depth-to-width aspect ratio is 10:1 or more.

Example 5 includes the subject matter of any of Examples 1-4, wherein the depth-to-width aspect ratio is 20:1 or more.

Example 6 includes the subject matter of any of Examples 1-5, wherein the width of the HAR feature is between 5 nm and 35 nm.

Example 7 includes the subject matter of any of Examples 1-6, wherein the width of the HAR feature is between 5 nm and 20 nm.

Example 8 includes the subject matter of any of Examples 1-7, wherein the width of the HAR feature is between 5 nm and 15 nm.

Example 9 includes the subject matter of any of Examples 1-8, wherein the width of the HAR feature is between 5 nm and 10 nm.

Example 10 includes the subject matter of any of Examples 1-9, wherein the depth of the HAR feature is between 25 nm and 200 nm.

Example 11 includes the subject matter of any of Examples 1-10, wherein the depth of the HAR feature is between 25 nm and 150 nm.

Example 12 includes the subject matter of any of Examples 1-11, wherein the depth of the HAR feature is between 25 nm and 100 nm.

Example 13 includes the subject matter of any of Examples 1-12, wherein the depth of the HAR feature is between 25 nm and 70 nm.

Example 14 includes the subject matter of any of Examples 1-13, wherein the depth of the HAR feature is between 25 nm and 50 nm.

Example 15 includes the subject matter of any of Examples 1-14, wherein the depth of the HAR feature is between 25 nm and 35 nm.

Example 16 includes the subject matter of any of Examples 1-15, wherein the semiconductor structure includes a plurality of semiconductor fins, and the HAR feature is between two of the semiconductor fins.

Example 17 includes the subject matter of Example 16, wherein at least one of the two semiconductor fins is part of a transistor structure.

Example 18 includes the subject matter device of Example 16, wherein the two semiconductor fins are part of a capacitor structure.

Example 19 includes the subject matter of any of Examples 1-18, wherein the HAR feature is within and in direct contact with a bulk body of semiconductor material.

Example 20 is an integrated circuit including: first and second semiconductor fins defining a trench between the fins, the trench having a depth of between 25 nanometers (nm) and 250 nm, a width of between 5 nm and 50 nm, and a depth-to-width aspect ratio of 5:1 or more; and a gap-fill material at least partially filling the trench, the gap-fill material including silicon and nitrogen and being free of a vertical seam along all vertical planes that run between opposing sides of the trench.

Example 21 includes the subject matter of Example 20, wherein the depth-to-width aspect ratio is at least 10:1.

Example 22 includes the subject matter of Example 20 or 21, wherein the width of the trench is between 5 nm and 20 nm.

Example 23 includes the subject matter of any of Examples 20-22, wherein the width of the trench is between 5 nm and 10 nm.

Example 24 includes the subject matter of any of Examples 20-23, wherein the fins are part of one or more transistor or capacitor structures.

Example 25 is a semiconductor process platform including: a process chamber; a plurality of precursor zones within the process chamber, each configured to deliver a separate precursor of a deposition cycle; a susceptor configured to hold a semiconductor wafer and to move relative to the zones to complete the deposition cycle on the wafer; and a nitrogen radical generator to generate nitrogen radicals for delivery to one of the zones.

Example 26 includes the subject matter of Example 25, wherein the nitrogen radical generator is a stand-alone nitrogen radical generator.

Example 27 includes the subject matter of Example 25, wherein the nitrogen radical generator has a dedicated delivery line to deliver the nitrogen radicals to the one of the zones.

Example 28 includes the subject matter of any of Examples 25-27, wherein the susceptor is one of a plurality of susceptors configured to concurrently move relative to the zones to complete the deposition cycle on a corresponding plurality of semiconductor wafers.

Example 29 includes the subject matter of Example 28, wherein the zones are arranged about an axis of rotation and the susceptors are configured to rotate about the axis through the zones.

Example 30 includes the subject matter of any of Examples 25-29, wherein platform is a spatial atomic layer deposition (S-ALD) platform.

Example 31 includes the subject matter of any of Examples 25-30, wherein the deposition cycle is an atomic layer deposition (ALD) cycle.

Example 32 is a semiconductor process platform including: a process chamber; a wafer handler to move a semiconductor wafer within or in-and-out of the process chamber; and a nitrogen radical generator having a dedicated delivery line and configured to deliver nitrogen radicals as part of a deposition cycle to the process chamber by the dedicated delivery line.

Example 33 includes the subject matter of Example 32, wherein the nitrogen radical generator is a stand-alone nitrogen radical generator.

Example 34 includes the subject matter of Example 32 or 33, wherein the platform is a spatial atomic layer deposition (S-ALD) platform.

Example 35 includes the subject matter of any of Examples 32-34, wherein the deposition cycle is an atomic layer deposition (ALD) cycle.

Example 36 is a method of semiconductor device fabrication including: forming one or more layers on a semiconductor substrate; forming a high aspect ratio (HAR) feature in one or more contiguous ones of the layers and substrate, the HAR feature having a depth of between 25 nanometers (nm) and 250 nm, a width of between 5 nm and 50 nm, and a depth-to-width aspect ratio of 5:1 or more; and filling the HAR feature with silicon nitride using an atomic layer deposition (ALD) process, the ALD process including a plurality of ALD cycles, at least one ALD cycle including reacting surfaces of the HAR feature with a silicon precursor to form a monolayer of the silicon precursor, and reacting the silicon-precursed surfaces with nitrogen plasma to form a monolayer of silicon nitride.

Example 37 includes the subject matter of Example 36, wherein the reacting of the silicon-precursed surfaces with nitrogen plasma includes supplying nitrogen radicals from a stand-alone nitrogen radical generator.

Example 38 includes the subject matter of Example 37, wherein the supplying of the nitrogen radicals includes supplying the nitrogen radicals from the stand-alone nitrogen radical generator via a dedicated delivery path.

Example 39 includes the subject matter of any of Examples 36-38, wherein the at least one ALD cycle further includes: removing unreacted portions of the silicon precursor from the HAR feature before the reacting of the silicon-precursed surfaces; and removing unreacted portions of the nitrogen plasma from the HAR feature before reacting the surfaces of the HAR feature with the silicon precursor during another one of the ALD cycles.

Example 40 includes the subject matter of any of Examples 36-39, wherein the silicon precursor includes one or more of silane, disilane, and dichlorosilane.

Example 41 includes the subject matter of any of Examples 36-40, wherein the HAR feature is a trench.

Example 42 includes the subject matter of any of Examples 36-41, wherein the ALD process is a spatial ALD (S-ALD) process.

Example 43 includes the subject matter of any of Examples 36-42, wherein the depth-to-width aspect ratio of the HAR feature is 7:1 or more.

Example 44 includes the subject matter of any of Examples 36-43, wherein the depth-to-width aspect ratio of the HAR feature is 10:1 or more.

Example 45 includes the subject matter of any of Examples 36-44, wherein the width of the HAR feature is between 5 nm and 20 nm.

Example 46 includes the subject matter of any of Examples 36-45, wherein the width of the HAR feature is between 5 nm and 10 nm.

Example 47 is a method of trench filling including: forming a trench in an integrated circuit structure, the trench having a depth of between 25 nanometers (nm) and 250 nm, a width of between 5 nm and 50 nm, and a depth-to-width aspect ratio of 5:1 or more; and filling the trench with silicon nitride using an atomic layer deposition (ALD) process, the ALD process including one or more ALD cycles, at least one ALD cycle including supplying nitrogen radicals from a nitrogen radical generator via a dedicated delivery path to allow cross-linking between approaching opposing surfaces of the silicon nitride as the silicon nitride conformally fills the trench, such that there is no seam between the opposing surfaces.

Example 48 includes the subject matter of Example 47, wherein one of the ALD cycles includes: reacting surfaces of the trench with a silicon precursor to form a monolayer of the silicon precursor; and reacting the silicon-precursed surfaces with the nitrogen radicals supplied by the dedicated delivery path to form a monolayer of silicon nitride.

Example 49 includes the subject matter of Example 48, wherein the one of the ALD cycles further includes: removing unreacted portions of the silicon precursor from the trench before the reacting of the silicon-precursed surfaces; and removing unreacted portions of the nitrogen radicals from the trench before reacting the surfaces of the trench with the silicon precursor during another one of the ALD cycles.

Example 50 includes the subject matter of Example 48 or 49, wherein the silicon precursor includes one or more of silane, disilane, and dichlorosilane.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1-25. (canceled)

26. An integrated circuit device comprising:
a structure comprising semiconductor material, the structure having a high aspect ratio (HAR) feature, the HAR feature having a depth of between 25 nanometers (nm) and 250 nm, a width of between 5 nm and 50 nm, and a depth-to-width aspect ratio of 5:1 or more; and
a gap-fill material at least partially filling the HAR feature, the gap-fill material comprising silicon and nitrogen and being substantially free of a seam located between opposing sides of the HAR feature.

27. The integrated circuit device of claim 26, wherein being substantially free of a seam means having a seam in no more than 25% of the gap-fill material within the HAR feature.

28. The integrated circuit device of claim 26, wherein being substantially free of a seam means being completely free of a vertical seam in the gap-fill material along all vertical planes between opposing sides of the HAR feature.

29. The integrated circuit device of claim 26, wherein the depth-to-width aspect ratio is 10:1 or more.

30. The integrated circuit device of claim 26, wherein the width of the HAR feature is between 5 nm and 35 nm.

31. The integrated circuit device of claim 26, wherein the width of the HAR feature is between 5 nm and 15 nm.

32. The integrated circuit device of claim 26, wherein the depth of the HAR feature is between 25 nm and 150 nm.

33. The integrated circuit device of claim 26, wherein the depth of the HAR feature is between 25 nm and 70 nm.

34. The integrated circuit device of claim 26, wherein the depth of the HAR feature is between 25 nm and 50 nm.

35. The integrated circuit device of claim 26, wherein the depth of the HAR feature is between 25 nm and 35 nm.

36. The integrated circuit device of claim 26, wherein the structure includes a plurality of fins, and the HAR feature is between two of the fins.

37. The integrated circuit device of claim 36, wherein at least one of the two fins is part of a transistor structure.

38. The integrated circuit device of claim 36, wherein the two fins are part of a capacitor structure.

39. The integrated circuit device of claim 26, wherein the HAR feature is within and in direct contact with a body comprising semiconductor material.

40. An integrated circuit comprising:
first and second fins defining a trench between the fins, the trench having a depth of between 25 nanometers (nm) and 250 nm, a width of between 5 nm and 50 nm, and a depth-to-width aspect ratio of 5:1 or more, the first and second fins comprising semiconductor material; and
a gap-fill material at least partially filling the trench, the gap-fill material comprising silicon and nitrogen and being free of a vertical seam along one or more vertical planes that run between opposing sides of the trench.

41. The integrated circuit of claim 40, wherein the depth-to-width aspect ratio is at least 10:1.

42. The integrated circuit of claim 40, wherein the width of the trench is between 5 nm and 20 nm.

43. The integrated circuit of claim 40, wherein the first and second fins are part of one or more transistor or capacitor structures.

44. A method of fabricating a device, the method comprising:
forming one or more layers on a substrate comprising semiconductor material;
forming a high aspect ratio (HAR) feature in one or more contiguous ones of the layers and substrate, the HAR feature having a depth of between 25 nanometers (nm) and 250 nm, a width of between 5 nm and 50 nm, and a depth-to-width aspect ratio of 5:1 or more; and
filling the HAR feature with material comprising silicon and nitrogen using an atomic layer deposition (ALD) process, the ALD process including a plurality of ALD cycles, at least one ALD cycle including
reacting surfaces of the HAR feature with a precursor comprising silicon to form a monolayer of the precursor, and
reacting the precursed surfaces with plasma comprising nitrogen to form a monolayer of silicon and nitrogen.

45. The method of claim 44, wherein the reacting of the precursed surfaces with plasma comprises supplying nitrogen radicals from a stand-alone nitrogen radical generator via a dedicated delivery path.
